(19) United States
(12) Patent Application Publication
(10) Pub. No.: US 2026/0136611 A1
(43) Pub. Date: May 14, 2026

(54) SEMICONDUCTOR STRUCTURE

(71) Applicants: NIKO SEMICONDUCTOR CO., LTD., New Taipei City (TW); SUPER GROUP SEMICONDUCTOR CO., LTD., Hsinchu County (TW)

(72) Inventors: Sung-Nien TANG, Hsinchu County (TW); Ho-Tai CHEN, Hsinchu County (TW); Hsiu-Wen HSU, Hsinchu County (TW)

(21) Appl. No.: 19/242,950

(22) Filed: Jun. 18, 2025

(30) Foreign Application Priority Data
Nov. 12, 2024 (TW) 113143307

(51) Int. Cl. H10D 62/10; H10D 30/66

(52) U.S. Cl. CPC H10D 62/109; H10D 30/668

(57) ABSTRACT

A semiconductor structure includes a substrate, a first doped type epitaxial layer, a gate structure, second doped type epitaxial layers, doped regions, and source regions. The first doped type epitaxial layer is disposed on the substrate. The gate structure is disposed on the first doped type epitaxial layer and extends in the first direction. The second doped type epitaxial layers are disposed on both sides of the gate structure and on the first doped type epitaxial layer, in which a bottom of the gate structure is lower than a bottom of the second doped type epitaxial layers. The doped regions are spaced apart in the first direction and cover a plurality of bottom corners on both sides of the gate structure. The source regions are disposed on both sides of the at least one gate structure and on the second doped type epitaxial layers.

This application claims priority to Taiwan Application Serial Number 113143307, filed November 12, 2024, which is herein incorporated by reference in its entirety.

### BACKGROUND

### Field of Invention

The present disclosure relates to a semiconductor structure.

### Description of Related Art

Compared to conventional planar MOS devices, in which the current flows along a plane on the substrate surface, trench MOS devices place the gate in a trench. This changes the channel position of the MOS device, causing the current flow of the MOS device to be perpendicular to the substrate. Thus, the size of the device can be reduced, the activeness of the device can be increased, and the production cost can be reduced. Common metal-oxide-semiconductor devices include metal-oxide-semiconductor field-effect transistor (MOSFET), insulated gate bipolar transistor (IGBT), etc.

While costs can be reduced by shrinking device geometries, various tradeoffs and challenges must be met when increasing device functionality per unit area. For example, reducing the on-resistance per unit area (RₒₙxA) may have an impact on other electrical device characteristics, such as device reliability may be limited by high electric fields in the trench dielectric (e.g., gate oxide).

In view of the above, a semiconductor structure that can improve the electrical characteristics of a trench MOS device needs to be provided.

### SUMMARY

The disclosure provides a semiconductor structure. The semiconductor structure includes a substrate, a first doped type epitaxial layer, at least one gate structure, a plurality of second doped type epitaxial layers, a plurality of doped regions, and a plurality of source regions. The first doped type epitaxial layer is disposed on the substrate. The at least one gate structure is disposed on the first doped type epitaxial layer and extends in the first direction. The second doped type epitaxial layers are disposed on both sides of the at least one gate structure and on the first doped type epitaxial layer, in which a bottom of the at least one gate structure is lower the bottoms of the second doped type epitaxial layers. The doped regions are spaced apart in the first direction and cover a plurality of bottom corners on both sides of the gate structure. The source regions are disposed on both sides of the at least one gate structure and on the second doped type epitaxial layers.

In some embodiments, the doped regions and the second doped type epitaxial layers have the same doping type, and a doping concentration of the doped regions is greater than a doping concentration of the second doped type epitaxial layers.

In some embodiments, the at least one gate structure includes a first gate structure and a second gate structure, and the first gate structure and the second gate structure are isolated by one of the second doped type epitaxial layers and are arranged in parallel in a second direction perpendicular to the first direction.

In some embodiments, the doped regions include a plurality of first left-side doped regions and a plurality of first right-side doped regions. The plurality of first left-side doped regions cover the bottom corners on a left side of the first gate structure. The plurality of first right-side doped regions cover the bottom corners on a right side of the first gate structure. The first left-side doped regions and the first right-side doped regions are symmetrically arranged about a first central axis of the first gate structure, and the first central axis is parallel to the first direction.

In some embodiments, the doped regions are spaced apart and parallel to the first direction, and a distance between any two adjacent doped regions is 0.5 micrometers to 2 micrometers.

In some embodiments, the doped regions include a plurality of first left-side doped regions and a plurality of first right-side doped regions. The plurality of first left-side doped regions cover the bottom corners on a left side of the first gate structure. The plurality of first right-side doped regions cover the bottom corners on a right side of the first gate structure, and the first left-side doped regions and the first right-side doped regions are alternately arranged in the second direction.

In some embodiments, the doped regions are spaced apart and parallel to the first direction, and a distance between any two adjacent doped regions is 1 micrometer to 4 micrometers.

In some embodiments, the doped regions include a plurality of second left-side doped regions and a plurality of second right-side doped regions. The plurality of second left-side doped regions cover the bottom corners on a left side of the second gate structure. The plurality of second right-side doped regions cover the bottom corners on a right side of the second gate structure, and the second left-side doped regions and the second right-side doped regions are arranged alternately in the second direction. The second left-side doped regions and the first right-side doped regions are symmetrically arranged with a center line between the first gate structure and the second gate structure as an axis, and the second right-side doped regions and the first left-side doped regions are symmetrically arranged with the center line as an axis.

In some embodiments, the doped regions include a plurality of second left-side doped regions and a plurality of second right-side doped regions. The plurality of second left-side doped regions cover the bottom corners on a left side of the second gate structure. The plurality of second right-side doped regions cover the bottom corners on a right side of the second gate structure, and the second left-side doped regions and the second right-side doped regions are arranged alternately in the second direction. The second left-side doped regions and the first right-side doped regions are arranged alternately in the second direction, and the second right-side doped regions and the first left-side doped regions are arranged alternately in the second direction.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a semiconductor structure according to various embodiments of the present disclosure.

FIG. 2 is a top view of a semiconductor structure according to various embodiments of the present disclosure.

FIG. 3A is a cross-sectional view of the semiconductor structure along line A-A of FIG. 2 according to various embodiments of the present disclosure.

FIG. 3B is a cross-sectional view of the semiconductor structure along line B-B of FIG. 2 according to various embodiments of the present disclosure.

FIG. 4 is a top view of a semiconductor structure according to various embodiments of the present disclosure.

FIG. 5A is a cross-sectional view of the semiconductor structure along line A-A of FIG. 4 according to various embodiments of the present disclosure.

FIG. 5B is a cross-sectional view of the semiconductor structure along line B-B of FIG. 4 according to various embodiments of the present disclosure.

FIG. 6 is a top view of a semiconductor structure according to various embodiments of the present disclosure.

FIG. 7A is a cross-sectional view of the semiconductor structure along line A-A of FIG. 6 according to various embodiments of the present disclosure.

FIG. 7B is a cross-sectional view of the semiconductor structure along line B-B of FIG. 6 according to various embodiments of the present disclosure.

### DETAILED DESCRIPTION

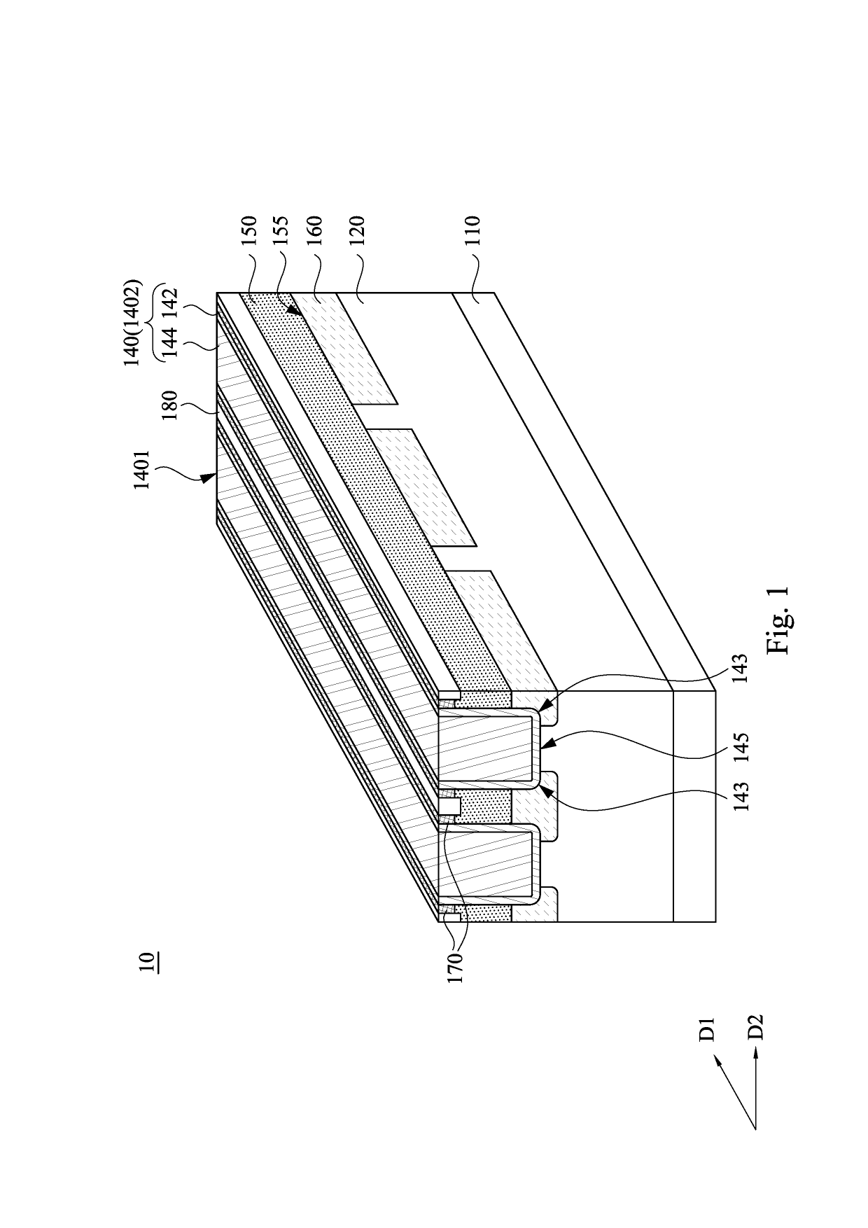

FIG. 1 is a perspective view of a semiconductor structure 10 according to various embodiments of the present disclosure. The embodiments of the present disclosure are related to a metal oxide semiconductor field effect transistor, and the figures are described using an N-type metal oxide semiconductor field effect transistor as an example. The semiconductor structure 10 includes a substrate 110 , a first doped type epitaxial layer 120, at least one gate structure 140, a plurality of second doped type epitaxial layers 150, a plurality of doped regions 160, and a plurality of source regions 170, as shown in FIG. 1. Specifically, the first doped type epitaxial layer 120 is disposed on the substrate 110. The at least one gate structure 140 is disposed on the first doped type epitaxial layer 120 and extends in the first direction D1.

In some embodiments, the substrate 110 may further include various doping substances, such as n-type wells and/or p-type wells formed by ion implantation and/or diffusion. In this embodiment, the substrate 110 is a heavily N-type doped (N+) silicon substrate. The heavily N-type doped silicon substrate serves as the drain of the power MOSFET structure. In some embodiments, the first doped type epitaxial layer 120 is, for example, an epitaxial layer with N-type light doping (N-). N+ indicates one having a higher concentration of N-type impurities, and N- indicates one having a lower concentration of N-type impurities.

In some embodiments, a mask pattern (not shown) may be used to define the position of the gate structure, and at least one trench (not shown) may be formed in the first doped type epitaxial layer 120 by etching. As shown, the trench may be strip-shaped and extend in the first direction D1. In some embodiments, the cross-sectional profile of the trench is rectangular, and the bottom corners on both sides are slightly rounded. Next, after removing the mask pattern, a gate oxide layer 142 is formed on the inner wall (including the side wall and the bottom surface) of the trench. In some embodiments, the gate oxide layer 142 includes silicon oxide, silicon nitride, or a high dielectric constant material with a dielectric constant of 4 or more. Then, a gate layer 144 is formed on the gate oxide layer 142 in the trench. In some embodiments, the gate layer 144 may include a metal or metal alloy layer and/or doped polysilicon. In other embodiments, metal silicide may be additionally formed on the doped polysilicon to reduce gate resistance. Generally speaking, the gate oxide layer 142 and the gate layer 144 may be collectively referred to as a gate structure 140. Therefore, the gate structure 140 also presents a strip shape extending along the first direction D1.

Please refer to FIG. 1, the plurality of second doped type epitaxial layers 150 are disposed on both sides of the at least one gate structure 140 and on the first doped type epitaxial layer 120. It should be noted that a bottom 145 of the at least one gate structure 140 is lower than a bottom 155 of the plurality of second doped type epitaxial layers 150. In some embodiments, after forming the at least one gate structure 140, a second doped type (P-type) dopant may be implanted into the first doped type epitaxial layer 120, and a high temperature process may be applied to diffuse the implanted second doped type (P-type) dopant to form a second doped type epitaxial layer 150 formed on the first doped type epitaxial layer 120. Although the surface region of the first doped type epitaxial layer 120 contains first doping type (N type) dopants, the concentration of these N type dopants is much lower than the implantation concentration of the second doping type (P type) dopants. Therefore, the existence of these N-type dopants does not affect the formation of the second doped type epitaxial layer 150.

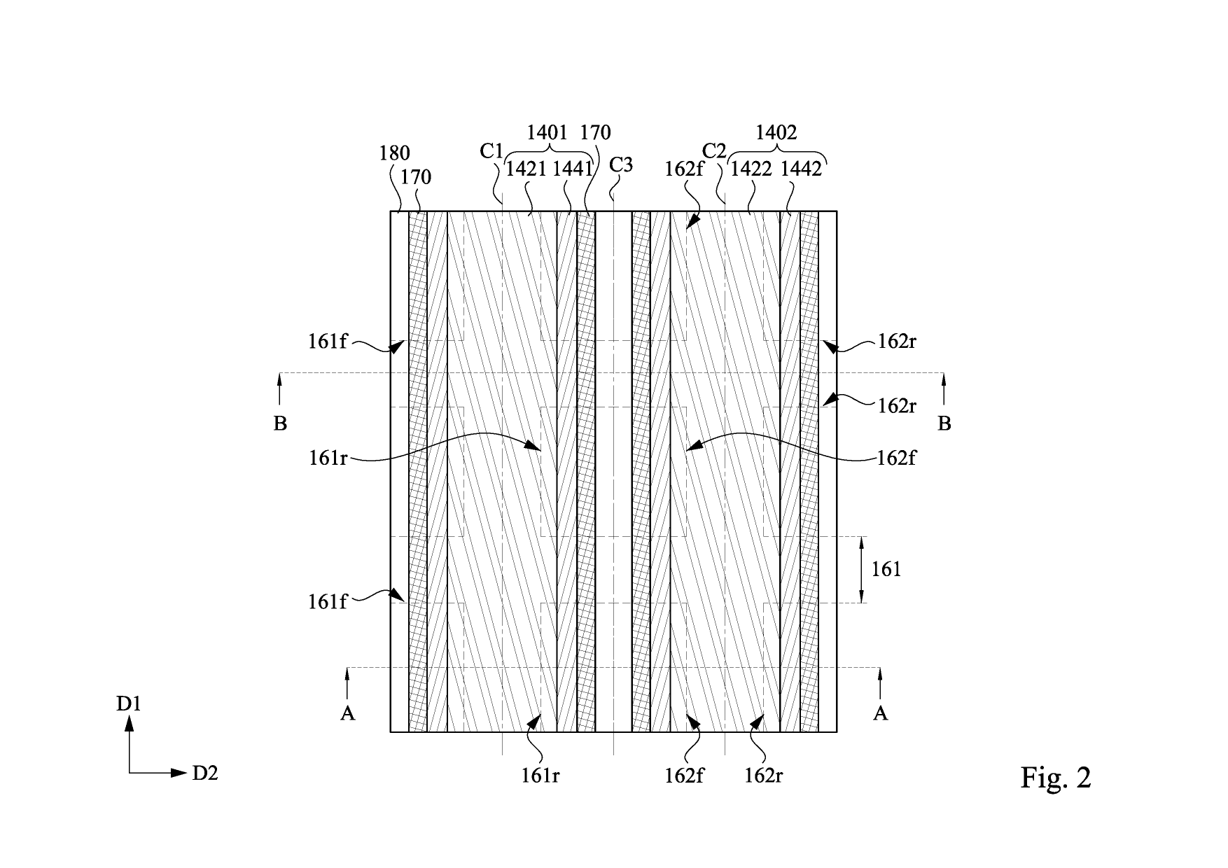

Continue to refer to FIG. 1. The plurality of doped regions 160 are disposed at intervals in the first direction D1 and cover a plurality of bottom corners 143 on both sides of the gate structure 140. In some embodiments, the doped regions 160 and the second doped type epitaxial layer 150 have the same doping type, such as P type. That is to say, these doped regions 160 may be P+ doped regions. It should be noted that a doping concentration of the doped regions 160 is greater than a doping concentration of the second doped type epitaxial layer 150. For example, the doping concentration of the doped regions 160 is 2 to 100 times the doping concentration of the second doped type epitaxial layer 150. In some embodiments, the doped regions 160 may be formed using an ion implantation process. In some embodiments, two adjacent doped regions 160 are spaced apart by a distance 161(in FIG. 2) in the first direction D1.

Continue to refer to FIG. 1. The plurality of source regions 170 are disposed on both sides of the at least one gate structure 140 and on the plurality of second doped type epitaxial layers 150. In some embodiments, the source regions 170 may be formed on both sides of the top of the gate structure 140 by ion implantation. In some embodiments, an interlayer dielectric layer (not shown) may be deposited to cover the gate layer 144 in the gate structure 140, and then the interlayer dielectric layer may be used as a mask to form a P-type heavily doped region 180 between two adjacent source regions 170 to enhance the device's ability to withstand avalanche energy. In this way, the manufacture of the MOS structure 10 is completed.

Therefore, it can be understood that the semiconductor structure 10 can be a vertical semiconductor device having a load current flowing in a direction vertical to the surface of the substrate 110. The vertical power semiconductor device can be configured to conduct currents greater than 1A or even greater than 100A, and can also be configured to block a voltage between load electrodes (e.g., between the drain and source of a MOSFET), where the voltage is in the range of hundreds to thousands of volts, such as 400V to 10.0kV. For example, the blocking voltage may correspond to a voltage level specified in a data sheet of the power semiconductor device.

When the size of the semiconductor structure 10 is smaller, it means that the gate structure area is reduced, so that the equivalent gate capacitance can be reduced. In addition, smaller gate structures usually have thinner gate oxide layers, which can reduce the unit resistance of the channel. However, such a change will also cause the semiconductor structure 10 to easily accumulate charges at the bottom corners on both sides of the gate structure when conducting high current, and even break through the thin gate oxide layer due to the quantum tunneling effect. Therefore, the plurality of doped regions spaced apart of the present disclosure are formed at the bottom corners on both sides of the gate structure to protect the gate structure, so as to increase the breakdown voltage at the bottom corners on both sides. For example, in the initial stage of starting up a semiconductor structure, the voltage is relatively small, so the current will be preferentially conducted through the channel of the undoped region. As more voltage is applied, current continues to flow through the channel having the doped region.

In some embodiments, the semiconductor structure 10 may include any number of gate structures 140. As shown in FIG. 1, although two gate structures 140 are shown, in some other embodiments, three or more gate structures 140 may be arranged along the second direction D2.

In some embodiments, when the at least one gate structure 140 is plural, the gate structures 140 at least include a first gate structure 1401 and a second gate structure 1402, and the first gate structure 1401 and the second gate structure 1402 are isolated by the second doped type epitaxial layer 150 and arranged in parallel in a second direction D2 perpendicular to the first direction D1.

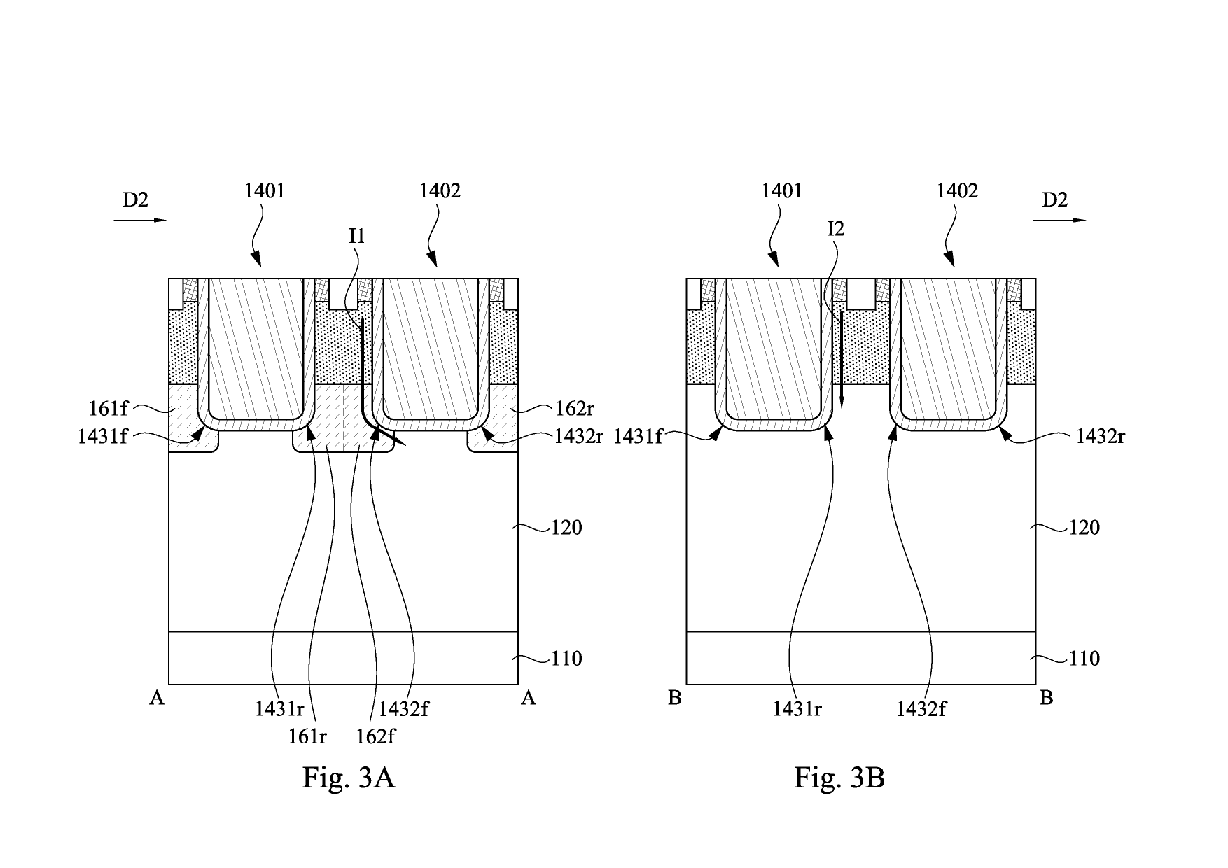

FIG. 2 is a top view of a semiconductor structure 10 according to other embodiments of the present disclosure. FIG. 3A is a cross-sectional view of the semiconductor structure along line A-A of FIG. 2. FIG. 3B is a cross-sectional view of the semiconductor structure along line B-B of FIG. 2. Please refer to FIG. 2, FIG. 3A, and FIG. 3B at the same time. The plurality of doped regions (indicated by dotted lines) include a plurality of first left-side doped regions 161f, a plurality of first right-side doped regions 161r, a plurality of second left-side doped regions 162f, and a plurality of second right-side doped regions 162r. To be specific, the first left-side doped regions 161f cover a plurality of bottom corners 1431f on a left side of the first gate structure 1401, and the first right-side doped regions 161r cover a plurality of bottom corners 1431r on a right side of the first gate structure 1401. The second left-side doped regions 162f cover a plurality of bottom corners 1432f on the left side of the second gate structure 1402, and the second right-side doped regions 162r cover a plurality of bottom corners 1432r on the right side of the second gate structure 1402.

In this embodiment, the first left-side doped regions 161f and the first right-side doped regions 161r are symmetrically arranged about the first central axis C1 of the first gate structure 1401 parallel to the first direction D1, and the second left-side doped regions 162f and the second right-side doped regions 162r are symmetrically arranged about the second central axis C2 of the second gate structure 1402 parallel to the first direction D1. It is worth noting that the second left-side doped regions 162f and the first right-side doped regions 161r are symmetrically arranged about a center line C3 between the first center axis C1 and the second center axis C2, and the second right-side doped regions 162r and the first left-side doped regions 161f are symmetrically arranged about the center line C3. In other words, with the center line C3 as the axis, the configuration relationship between the first left-side doped regions 161f and the first right-side doped regions 161r and the first gate structure 1401 and the configuration relationship between the second left-side doped regions 162f and the second right-side doped regions 162r and the second gate structure 1402 are bilaterally symmetrical mirror images.

In the embodiments as shown in FIGS. 2, 3A, and 3B, a distance 161 between any two adjacent ones of the doped regions (including the first left-side doped region 161f, the first right-side doped region 161r, the second left-side doped region 162f, and the second right-side doped region 162r) parallel to the first direction D1 is 0.5 micrometers to 2 micrometers. FIG. 3A shows a channel I1 with a high threshold voltage, while FIG. 3B shows a channel I2 with a low threshold voltage. The two channels I1 and I2 can improve the on-resistance of the overall semiconductor structure and form a dual threshold voltage (Dual) conduction characteristic, and enhance the linear region operating range.

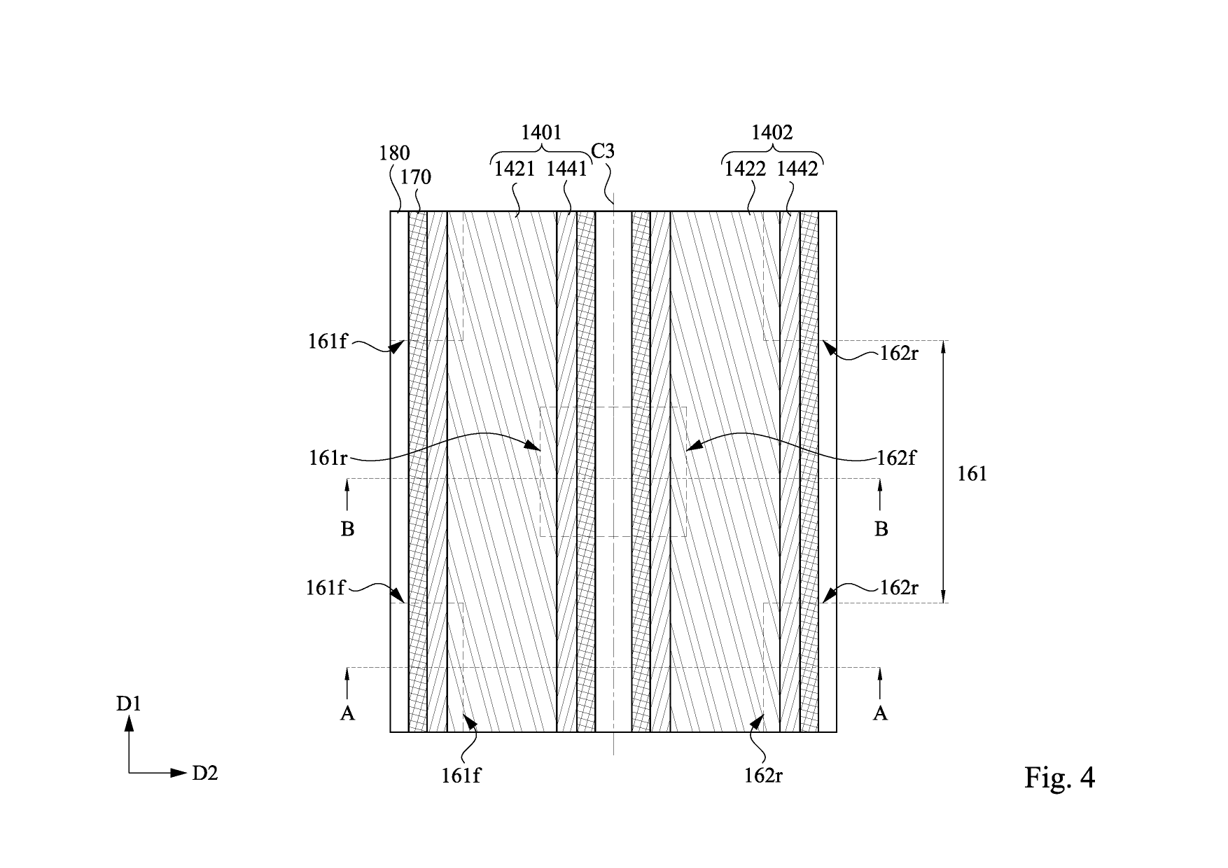

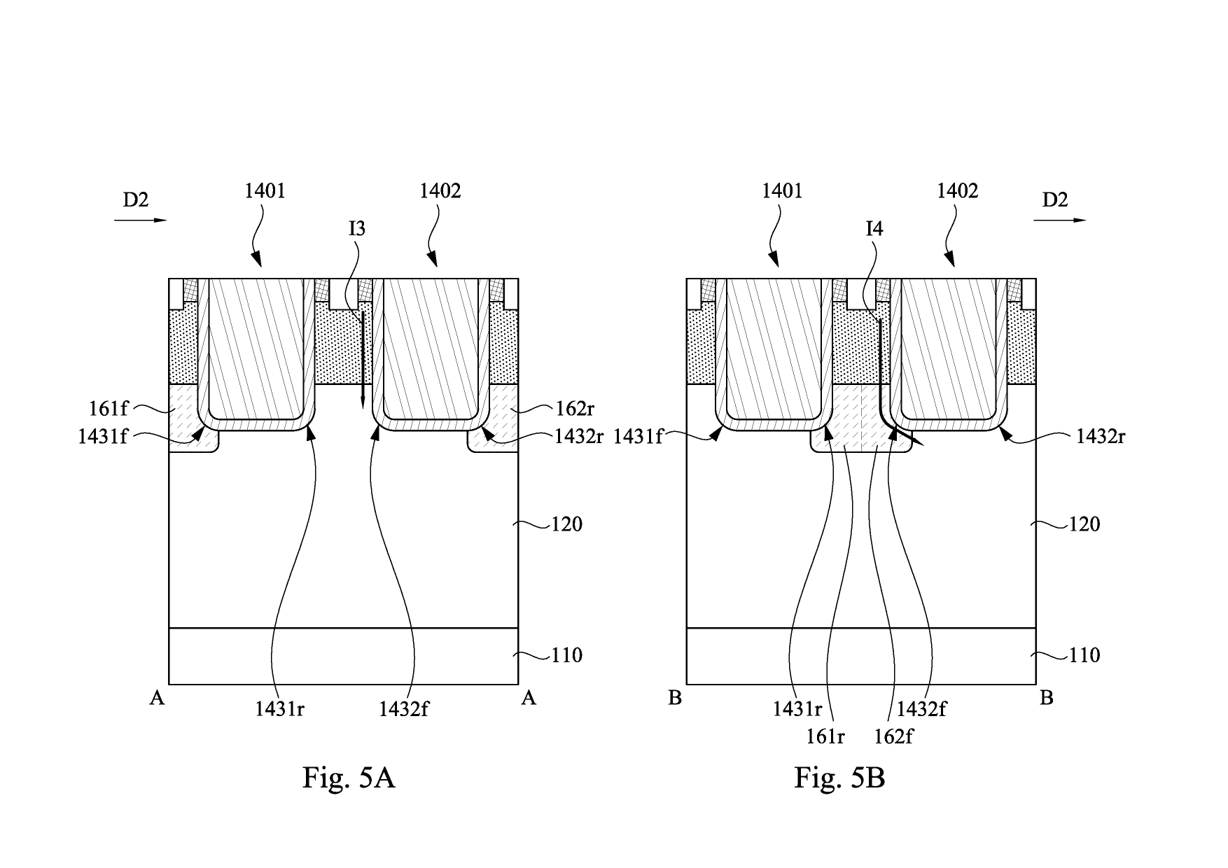

FIG. 4 is a top view of a semiconductor structure according to other embodiments of the present disclosure. FIG. 5A is a cross-sectional view of the semiconductor structure along line A-A of FIG. 4. FIG. 5B is a cross-sectional view of the semiconductor structure along line B-B of FIG. 4. Please refer to FIG. 4, FIG. 5A, and FIG. 5B at the same time. The plurality of doped regions (indicated by dotted lines) include a plurality of first left-side doped regions 161f, a plurality of first right-side doped regions 161r, a plurality of second left-side doped regions 162f, and a plurality of second right-side doped regions 162r. To be specific, the first left-side doped regions 161f cover a plurality of bottom corners 1431f on a left side of the first gate structure 1401, and the first right-side doped regions 161r cover a plurality of bottom corners 1431r on a right side of the first gate structure 1401. The second left-side doped regions 162f cover a plurality of bottom corners 1431f on the left side of the second gate structure 1402, and the second right-side doped regions 162r cover a plurality of bottom corners 1432r on the right side of the second gate structure 1402.

In this embodiment, the first left-side doped region 161f and the first right-side doped region 161r are arranged alternately (staggered or misaligned) in the second direction D2, and the second left-side doped region 162f and the second right-side doped region 162r are arranged alternately (staggered or misaligned) in the second direction D2, as shown in FIG. 4. It is worth noting that the second left-side doped regions 162f and the first right-side doped regions 161r are symmetrically arranged with a center line C3 between the first gate structure 1401 and the second gate structure 1402 as the axis, and the second right-side doped regions 162r and the first left-side doped regions 161f are symmetrically arranged with the center line C3 as the axis. In other words, with the center line C3 as the axis, the configuration relationship between the first left-side doped regions 161f and the first right-side doped regions 161r and the first gate structure 1401 and the configuration relationship between the second left-side doped regions 162f and the second right-side doped regions 162r and the second gate structure 1402 are bilaterally symmetrical mirror images.

In the embodiments as shown in FIGS. 4, 5A, and 5B, a distance 161 between any two adjacent ones of the doped regions (including the first left-side doped region 161f, the first right-side doped region 161r, the second left-side doped region 162f, and the second right-side doped region 162r) parallel to the first direction D1 is 1 micrometer to 4 micrometers. Compared to the embodiments shown in FIG. 2, FIG. 3A and FIG. 3B , the distance between two adjacent doped regions in this embodiment is larger, and therefore, the doping concentration of each doped region is also larger. For example, the doping concentration of the doped region shown in FIG. 4 is 1.5 to 5 times the doping concentration of the doped region shown in FIG. 2. FIG. 5A shows a channel I3 with a low threshold voltage, while FIG. 5B shows a channel I4 with a high threshold voltage. The two channels I3 and I4 can improve the on-resistance of the overall semiconductor structure and form a dual threshold voltage (Dual) conduction characteristic, and enhance the linear region operating range.

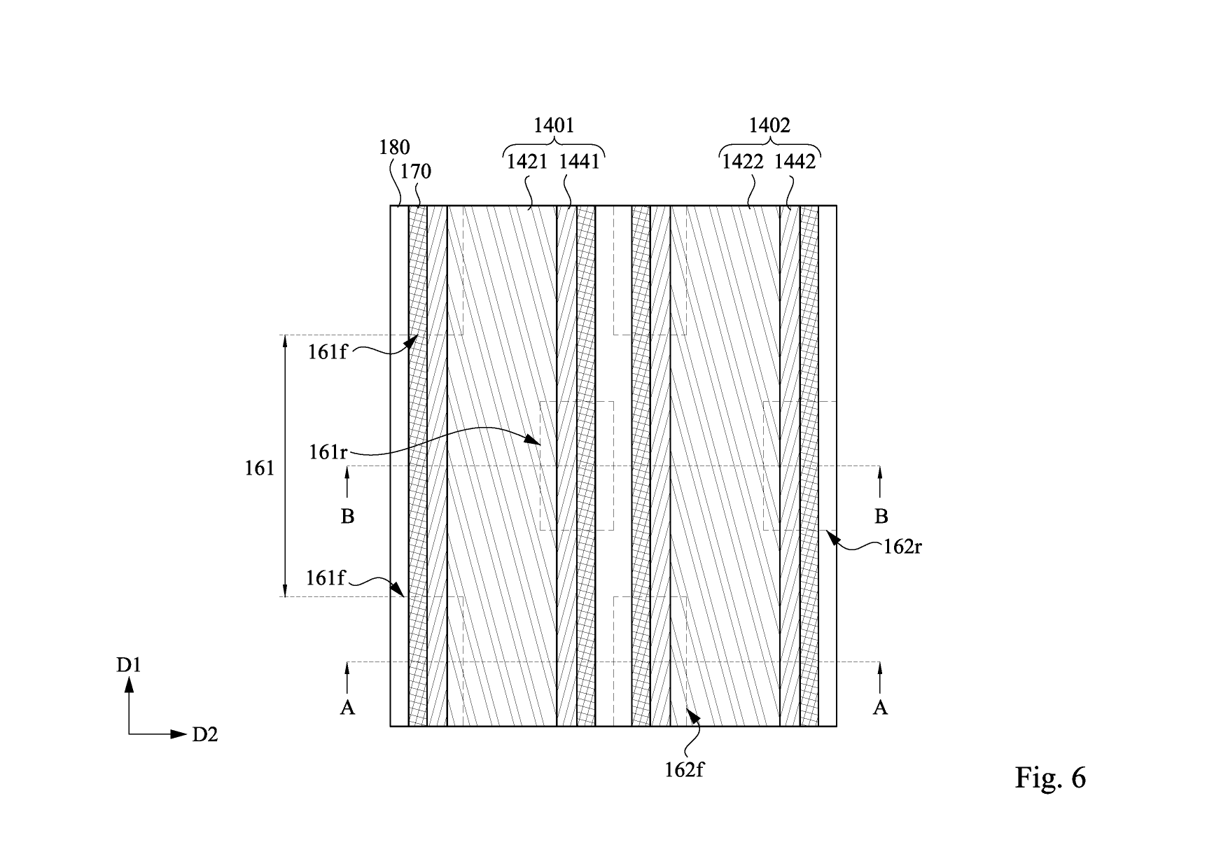

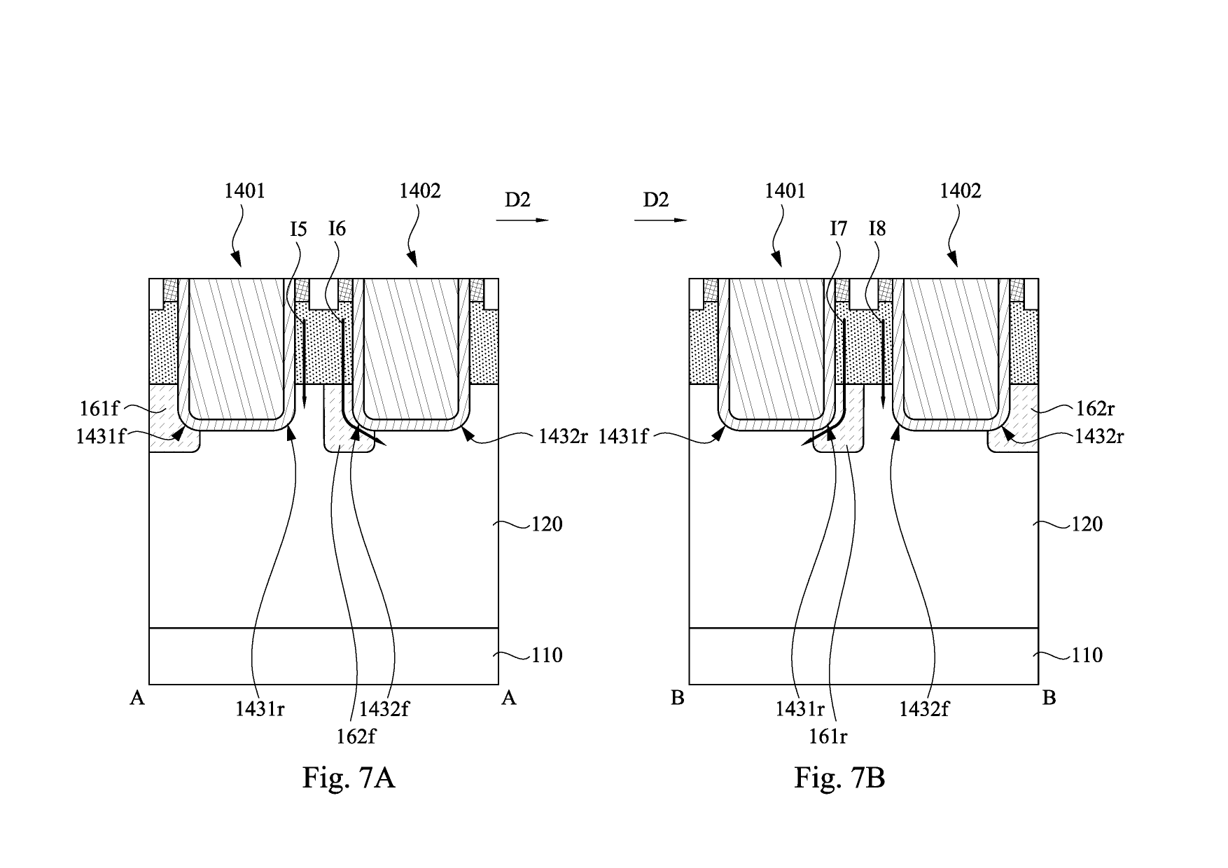

FIG. 6 is a top view of a semiconductor structure according to other embodiments of the present disclosure. FIG. 7A is a cross-sectional view of the semiconductor structure along line A-A of FIG. 6. FIG. 7B is a cross-sectional view of the semiconductor structure along line B-B of FIG. 6. Please refer to FIG. 6, FIG. 7A, and FIG. 7B at the same time. The plurality of doped regions (indicated by dotted lines) include a plurality of first left-side doped regions 161f, a plurality of first right-side doped regions 161r, a plurality of second left-side doped regions 162f, and a plurality of second right-side doped regions 162r. To be specific, the first left-side doped regions 161f cover a plurality of bottom corners 1431f on a left side of the first gate structure 1401, and the first right-side doped regions 161r cover a plurality of bottom corners 1431r on a right side of the first gate structure 1401. The second left-side doped regions 162f cover a plurality of bottom corners 1431f on the left side of the second gate structure 1402, and the second right-side doped regions 162r cover a plurality of bottom corners 1432r on the right side of the second gate structure 1402.

In this embodiment, the first left-side doped region 161f and the first right-side doped region 161r are arranged alternately (staggered or misaligned) in the second direction D2, and the second left-side doped region 162f and the second right-side doped region 162r are arranged alternately (staggered or misaligned) in the second direction D2. It is worth noting that the second left-side doped regions 162f and the first right-side doped regions 161r are arranged alternately in the second direction D2, and the second right-side doped regions 162r and the first left-side doped regions 161f are arranged alternately in the second direction D2. In other words, with the center line C3 as the axis, the configuration relationship between the first left-side doped regions 161f and the first right-side doped regions 161r and the first gate structure 1401 and the configuration relationship between the second left-side doped regions 162f and the second right-side doped regions 162r and the second gate structure 1402 are designed to be translational in lateral direction.

In the embodiments as shown in FIGS. 6, 7A, and 7B, a distance 161 between any two adjacent ones of the doped regions (including the first left-side doped region 161f, the first right-side doped region 161r, the second left-side doped region 162f, and the second right-side doped region 162r) parallel to the first direction D1 is 1 micrometer to 4 micrometers. Compared to the embodiments shown in FIG. 2, FIG. 3A and FIG. 3B, the distance between two adjacent doped regions in this embodiment is larger, and therefore, the doping concentration of each doped region is also larger. For example, the doping concentration of the doped region shown in FIG. 6 is 1.5 to 5 times the doping concentration of the doped region shown in FIG. 2. FIG. 7A has channels I5 and I6, and FIG. 7B has channels I7 and I8. The dual channels can improve the on-resistance of the overall semiconductor structure and form a dual threshold voltage (Dual) conduction characteristic, and enhance the linear region operating range.

Compared to the embodiments of FIGS. 2, 3A and 3B, in the embodiments shown in FIGS. 4, 5A, 5B, 6, 7A and 7B, adjacent doped regions have a greater distance in either the first direction D1 or the second direction D2. Therefore, the semiconductor structure of the embodiments shown in FIGS. 4, 5A, 5B, 6, 7A, and 7B, has improved on-resistance (Ron).

In summary, the semiconductor structure of the present disclosure has multiple discontinuous doped regions covering multiple bottom corners on both sides of the gate structure, which can not only be used to protect the gate structure from electrical breakdown under high voltage, but also improve the on-resistance and dual threshold voltage conduction characteristics of the overall semiconductor structure and enhance the linear region operating range.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a first doped type epitaxial layer disposed on a substrate;
at least one gate structure disposed on the first doped type epitaxial layer and extending in a first direction;
a plurality of second doped type epitaxial layers disposed on both sides of the at least one gate structure and on the first doped type epitaxial layer, wherein a bottom of the at least one gate structure is lower than a bottom of the second doped type epitaxial layers;
a plurality of doped regions spaced apart in the first direction and covering a plurality of bottom corners on both sides of the at least one gate structure; and
a plurality of source regions disposed on both sides of the at least one gate structure and on the second doped type epitaxial layers.

2. The semiconductor structure of claim 1, wherein the doped regions and the second doped type epitaxial layers have the same doping type, and a doping concentration of the doped regions is greater than a doping concentration of the second doped type epitaxial layers.

3. The semiconductor structure of claim 1, wherein the at least one gate structure comprises a first gate structure and a second gate structure, and the first gate structure and the second gate structure are isolated by one of the second doped type epitaxial layers and are arranged in parallel in a second direction perpendicular to the first direction.

4. The semiconductor structure of claim 3, wherein the doped regions comprise:
a plurality of first left-side doped regions covering the bottom corners on a left side of the first gate structure; and
a plurality of first right-side doped regions covering the bottom corners on a right side of the first gate structure, the first left-side doped regions and the first right-side doped regions are symmetrically arranged about a first central axis of the first gate structure, and the first central axis is parallel to the first direction.

5. The semiconductor structure of claim 4, wherein the doped regions are spaced apart and parallel to the first direction, and a distance between any two adjacent doped regions is 0.5 micrometers to 2 micrometers.

6. The semiconductor structure of claim 3, wherein the doped regions comprise:
a plurality of first left-side doped regions covering the bottom corners on a left side of the first gate structure; and
a plurality of first right-side doped regions covering the bottom corners on a right side of the first gate structure, and the first left-side doped regions and the first right-side doped regions alternately arranged in the second direction.

7. The semiconductor structure of claim 6, wherein the doped regions are spaced apart and parallel to the first direction, and a distance between any two adjacent doped regions is 1 micrometer to 4 micrometers.

8. The semiconductor structure of claim 6, wherein the doped regions comprise:
a plurality of second left-side doped regions covering the bottom corners on a left side of the second gate structure; and
a plurality of second right-side doped regions covering the bottom corners on a right side of the second gate structure, and the second left-side doped regions and the second right-side doped regions arranged alternately in the second direction, wherein the second left-side doped regions and the first right-side doped regions are symmetrically arranged with a center line between the first gate structure and the second gate structure as an axis, and the second right-side doped regions and the first left-side doped regions are symmetrically arranged with the center line as an axis.

9. The semiconductor structure of claim 6, wherein the doped regions comprise:
a plurality of second left-side doped regions covering the bottom corners on a left side of the second gate structure; and
a plurality of second right-side doped regions covering the bottom corners on a right side of the second gate structure, and the second left-side doped regions and the second right-side doped regions arranged alternately in the second direction, wherein the second left-side doped regions and the first right-side doped regions are arranged alternately in the second direction, and the second right-side doped regions and the first left-side doped regions are arranged alternately in the second direction.
